(19) United States
(12) Patent Application Publication
(10) Pub. No.: US 2010/0012996 A1
(43) Pub. Date: Jan. 21, 2010

(54) DYNAMIC RANDOM ACCESS MEMORY STRUCTURE

(75) Inventor: TSUNG DE LIN, TAICHUNG CITY (TW)

Correspondence Address: WPAT, PC;INTELLECTUAL PROPERTY ATTORNEYS, 2030 MAIN STREET, SUITE 1300, IRVINE, CA, 92614, US

(73) Assignee: PROMOS TECHNOLOGIES INC., HSINCHU (TW)

(21) Appl. No.: 12/174,067

(22) Filed: Jul. 16, 2008

(51) Int. Cl. H01L 29/94

(52) U.S. Cl. 257/306; 257/E29.345

(57) ABSTRACT

A dynamic random access memory structure comprises a substrate having a first diffusion region and a second diffusion region, a dielectric structure overlaying the substrate, a capacitor contact plug disposed in the dielectric structure and connected to the first diffusion region, a bit-line contact plug disposed in the dielectric structure and connected to the second diffusion region, a metal silicide disposed on the capacitor contact plug, and a capacitive structure disposed on the dielectric structure and connected to the metal silicide.

### BACKGROUND OF THE INVENTION

(A) Field of the Invention

The present invention relates to a dynamic random access memory (DRAM) structure and method for preparing the same, and more particularly, to a dynamic random access memory structure with a metal silicide sandwiched between a capacitor contact plug and a bottom electrode of the stack capacitor and method for preparing the same.

(B) Description of the Related Art

A DRAM memory cell generally consists of a metal oxide semiconductor field effect transistor and a capacitor on a silicon substrate, and the transistor includes a source electrode electrically connected to an upper storage plate of the capacitor. There are two types of capacitors: stack capacitors and deep trench capacitors. The stack capacitor is fabricated on the surface of the silicon substrate, while the deep trench capacitor is fabricated inside the silicon substrate. Recently, the integration of the DRAM has increased rapidly along with the innovation of semiconductor fabrication technology. However, the size of the memory cell must be reduced to achieve the purpose of high integration, i.e., increased integration requires reductions in the size of the transistor and the capacitor.

From the fabrication sequence point view, the structure of the stack capacitor can be classified into COB (capacitor over bit line) structure and CUB (capacitor under bit line) structure. The significant difference between the COB and the CUB is the time at which the capacitor is formed, i.e., after forming the bit line (COB) or before forming the bit line (CUB). The COB structure has an advantage in that the capacitor can be formed without regard to the bit line process margin since the capacitor is formed after the bit line formation. Therefore, it has a relatively higher capacitance in comparison with the CUB structure. In contrast, in the CUB structure, the bit line design rule limits the process margin for buried contacts formation for electrical connection to the storage electrode and the switch transistor.

### SUMMARY OF THE INVENTION

One aspect of the present invention provides a dynamic random access memory structure with a metal silicide sandwiched between a capacitor contact plug and a bottom electrode of the stack capacitor. A dynamic random access memory structure according to this aspect of the present invention comprises a substrate having a first diffusion region and a second diffusion region, a dielectric structure overlaying the substrate, a capacitor contact plug disposed in the dielectric structure and connected to the first diffusion region, a bit-line contact plug disposed in the dielectric structure and connected to the second diffusion region, a metal silicide disposed on the capacitor contact plug, and a capacitive structure disposed on the dielectric structure and connected to the metal silicide.

Another aspect of the present invention provides a method for preparing a dynamic random access memory structure comprising the steps of forming a first diffusion region and a second diffusion region in a substrate, forming a first dielectric structure overlaying the substrate, forming a capacitor contact plug in the first dielectric structure and connected to the first diffusion region, forming a metal silicide on the capacitor contact plug, and forming a capacitive structure on the first dielectric structure and connected to the metal silicide. In particular, the forming of the capacitive structure comprises the steps of forming a second dielectric structure on the metal silicide, performing an etching process to remove a portion of the insulation layer to form a trench exposing the metal silicide, and forming a stack capacitor in the trench and connected to the metal silicide, wherein the etching process uses the metal silicide as an etching stop.

The etching selectivity between the metal silicide and the dielectric structure is very high; therefore, the metal silicide is used as the etching stop layer for the capacitor contact plug during the etching process and can effectively prevent the capacitor contact plug from being etched.

The foregoing has outlined rather broadly the features and technical advantages of the present invention in order that the detailed description of the invention that follows may be better understood. Additional features and advantages of the invention will be described hereinafter, which form the subject of the claims of the invention. It should be appreciated by those skilled in the art that the conception and specific embodiment disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

The objectives and advantages of the present invention will become apparent upon reading the following description and upon reference to the accompanying drawings in which:

FIG. 1 to FIG. 7 illustrate a method for preparing a dynamic random access memory structure according to one embodiment of the present invention.

### DETAILED DESCRIPTION OF THE INVENTION

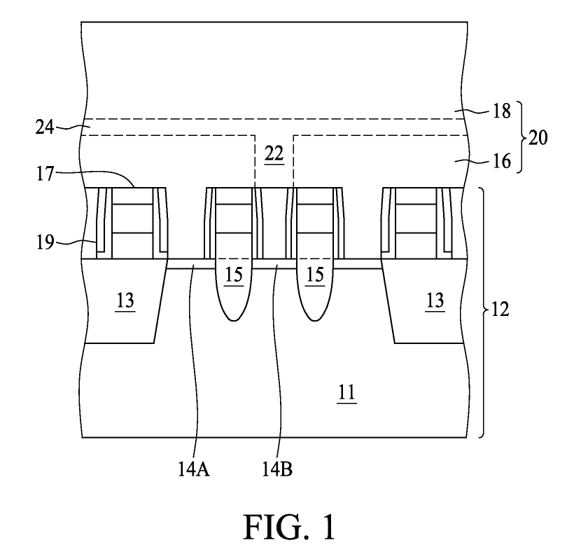

FIG. 1 to FIG. 7 illustrate a method for preparing a dynamic random access memory structure 10 according to one embodiment of the present invention. First, a first diffusion region 14A and a second diffusion region 14B are formed in a substrate 12 by the implanting process followed by the thermal diffusion process, and a dielectric structure 20 overlaying the substrate 12 is then formed by the deposition process. In particular, the substrate 12 includes a semiconductor substrate 11 with a shallow trench isolation 13, two recessed gates 15 positioned at two sides of the second diffusion region 14B in the semiconductor substrate 11, conductive lines 17 serving as word lines positioned on the recess gates 15, and double spacer structures 19 positioned on the sidewall of the conductive lines 17.

The forming of the dielectric structure 20 includes the steps of forming a first insulation layer 16 such as an HDP (high density plasma) oxide layer overlaying the substrate 12, forming a bit-line contact plug 22 in the first insulation layer 16 and connected to the second diffusion region 14B, forming a second insulation layer 18 such as a boro-phospho-silicate glass (BPSG) layer overlaying the first insulation layer 16, and forming a bit line 24 in the second insulation layer 18 and connected to the bit-line contact plug 22. The bit-line contact plug 22 and the bit line 24 are shown as a dashed line to emphasize that the bit-line contact plug 22 and the bit line 24 are buried in the dielectric structure 20.

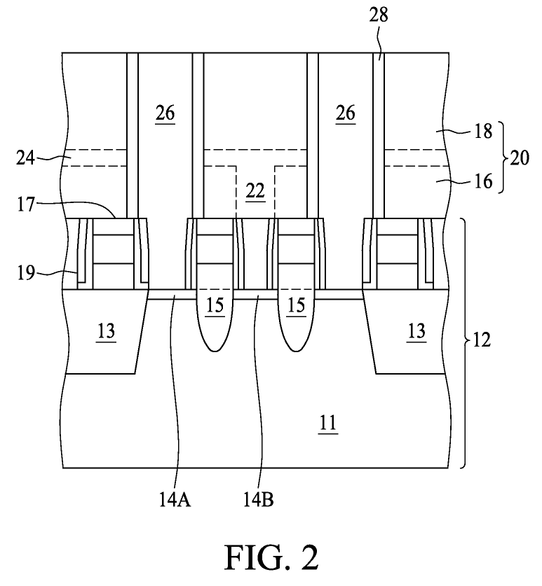

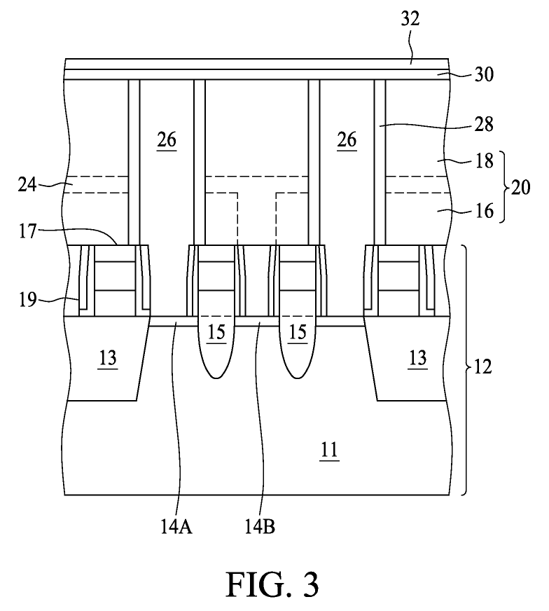

Referring to FIG. 2, a capacitor contact plug 26 is formed in the dielectric structure 20 and connects to the first diffusion region 14A. A buffer layer 28 is sandwiched between the capacitor contact plug 26 and the dielectric structure 20, the capacitor contact plug 26 may include polysilicon, and the buffer layer 28 may include nitride. Subsequently, a metal layer 30 is formed on the capacitor contact plug 26 and a metal nitride layer 32 is then formed on the metal layer 30 by a deposition process such as the physical vapor deposition (PVD), as shown in FIG. 3. The metal nitride layer 32 is used to prevent the metal layer 30 from being oxidized, and a metal oxide layer may be used to replace the metal nitride layer 32. The metal layer 30 may contain tungsten, cobalt, molybdenum, nickel, titanium, or rare earth metals.

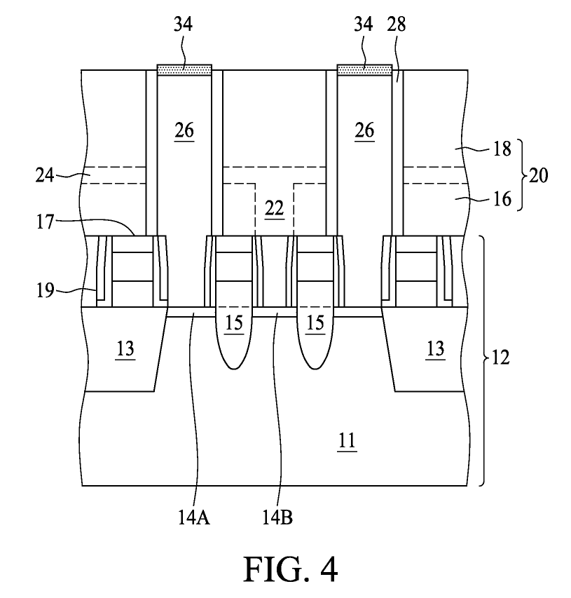

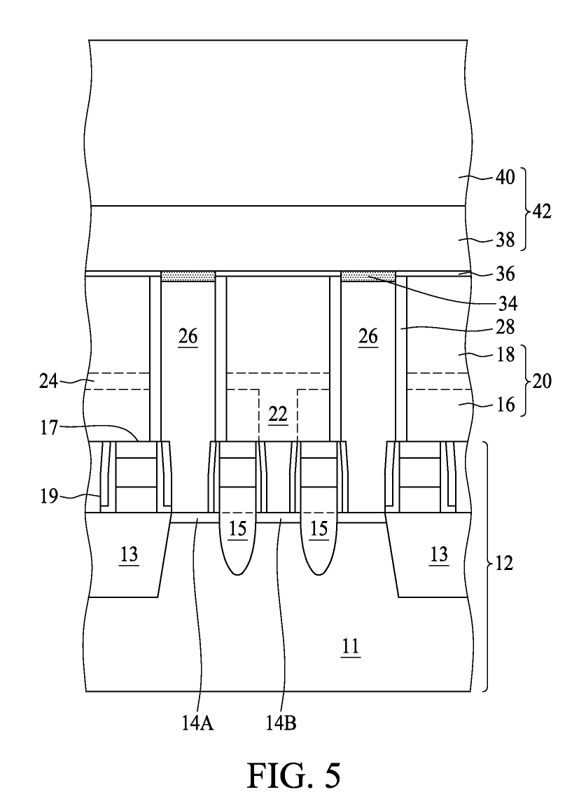

Referring to FIG. 4, a thermal treating process such as the rapid thermal process (RTP) is performed to convert a portion of the metal layer 30 and the capacitor contact plug 26 into a metal silicide 34 on the capacitor contact plug 26, and the other portion of the metal layer 30 not reacted with the capacitor contact plug 26 is then removed together with the metal nitride layer 32. In particular, the metal silicide 34 has an uppermost surface substantially higher than the top surface of the dielectric structure 20. Subsequently, a silicon nitride layer 36 is formed on the dielectric structure 20 by the deposition process, and a dielectric structure 42 overlaying the silicon nitride layer 26 is then formed by the deposition process, as shown in FIG. 5. In particular, the dielectric structure 42 may include a first insulation layer 38 such as a phosphosilicate glass (PSG) layer and a second insulation layer 40 such as a tetra-ethoxysilane (TEOS) layer.

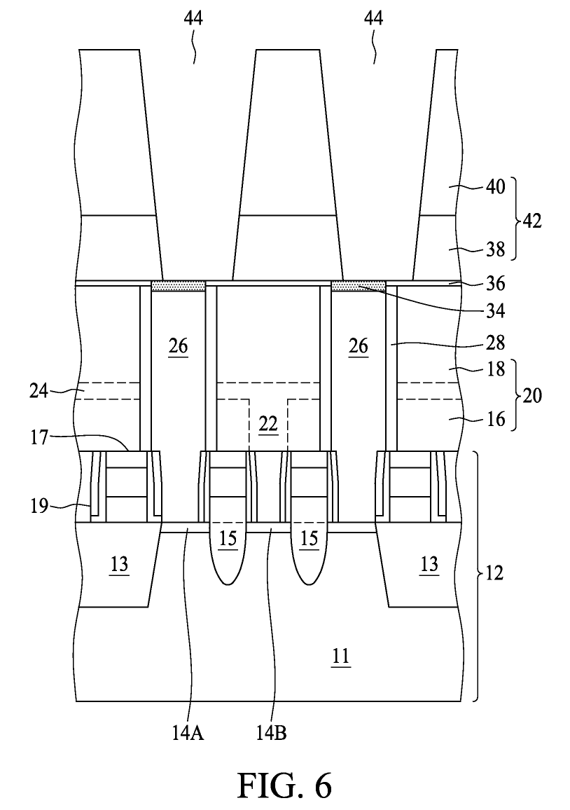

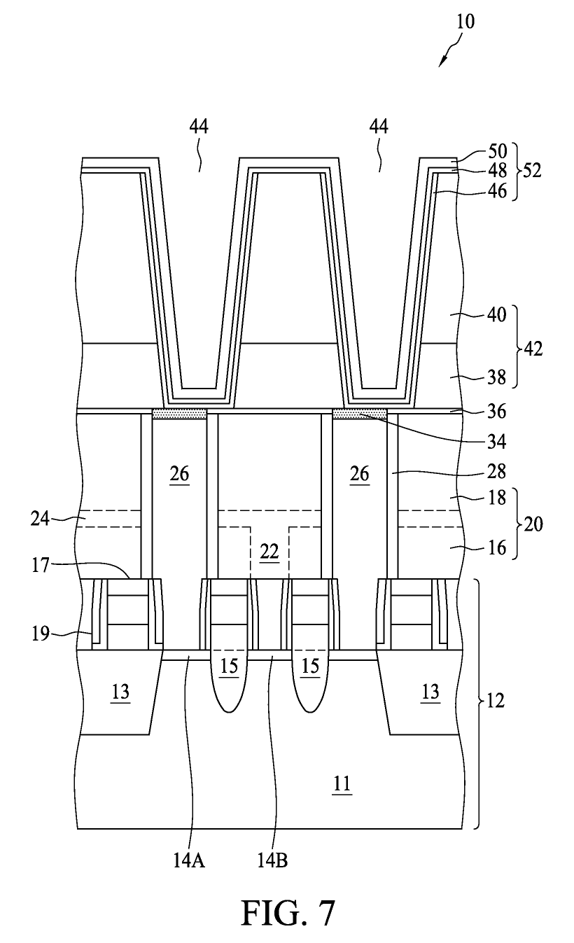

Referring to FIG. 6, a photolithographic process and an etching process are performed to remove a portion of the dielectric structure 42 to form two trenches 44 in the dielectric structure 42, wherein the trenches 42 expose the metal silicide 34 on the capacitor contact plug 26. In particular, the silicon nitride layer 36 is used as the etching stop layer for the dielectric structure 42 and the metal silicide 34 is used as the etching stop layer for the capacitor contact plug 26 during the etching process to form the two trenches 44. Subsequently, a deposition process is performed to form two stack capacitors 52 in the trenches 44 so as to complete the dynamic random access memory structure 10, wherein the stack capacitors 52 comprise a conductive layer 46, a dielectric layer 48 and a conductive layer 50, as shown in FIG. 7.

The metal silicide 34 is sandwiched between the capacitor contact plugs 26 made of polysilicon and the conductive layer 46 serving as a bottom electrode of the stack capacitor 52. The etching selectivity between the metal silicide 34 and the dielectric material (PSG and TEOS) of the dielectric structure 42 is very high; therefore, the metal silicide 34 is used as the etching stop layer for the capacitor contact plug 26 during the etching process to form the two trenches 44 and can effectively prevent the capacitor contact plug 26 from being etched.

Although the present invention and its advantages have been described in detail, it should be understood that various changes, substitutions and alterations can be made herein without departing from the spirit and scope of the invention as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A dynamic random access memory structure, comprising:
a substrate having a first diffusion region and a second diffusion region;
a dielectric structure overlaying the substrate;
a capacitor contact plug disposed in the dielectric structure and connected to the first diffusion region;
a bit-line contact plug disposed in the dielectric structure and connected to the second diffusion region;
a metal silicide disposed on the capacitor contact plug; and
a capacitive structure disposed on the dielectric structure and connected to the metal silicide.

2. The dynamic random access memory structure of claim 1, wherein the metal silicide includes titanium silicide.

3. The dynamic random access memory structure of claim 1, wherein the capacitor contact plug includes polysilicon.

4. The dynamic random access memory structure of claim 1, wherein the capacitive structure is positioned over the bit-line contact plug.

5. The dynamic random access memory structure of claim 1, further comprising a buffer layer sandwiched between the capacitor contact plug and the dielectric structure.

6. The dynamic random access memory structure of claim 5, wherein the buffer layer includes nitride.

7. The dynamic random access memory structure of claim 1, wherein the dielectric structure include a first insulation layer overlaying the substrate and a second insulation layer overlaying the first insulation layer.

8. The dynamic random access memory structure of claim 7, wherein the bit-line contact plug is positioned in the first insulation layer.

9. The dynamic random access memory structure of claim 7, further comprising a bit line positioned in the second insulation layer and connected to the bit-line contact plug.

10. The dynamic random access memory structure of claim 1, wherein the metal silicide has an uppermost surface substantially higher than a top surface of the dielectric structure.

11. A dynamic random access memory structure, comprising:
a semiconductor substrate;
a plurality of gates and diffusion regions formed in the semiconductor substrate;
a dielectric structure overlaying the semiconductor substrate and covering the gates;
a plurality of polysilicon plugs embedded in the dielectric structure, wherein one end of the polysilicon plugs is connected to the diffusion region;
a silicide layer formed on an upper surface of the polysilicon plugs; and
a silicon nitride layer formed on the silicide layer and the dielectric structure.

12. The dynamic random access memory structure of claim 11, wherein the silicide layer is titanium silicide.

13. The dynamic random access memory structure of claim 11, wherein the dielectric structure include a first insulation layer overlaying the substrate and a second insulation layer overlaying the first insulation layer.

14. The dynamic random access memory structure of claim 13, wherein the bit-line contact plug is positioned in the first insulation layer.

15. The dynamic random access memory structure of claim 14, further comprising a bit line positioned in the second insulation layer and connected to the bit-line contact plug.

16. The dynamic random access memory structure of claim 11, wherein the silicide layer has an uppermost surface substantially higher than a top surface of the dielectric structure.
